(19) United States
(12) Patent Application Publication
(10) Pub. No.: US 2005/0184747 A1
(43) Pub. Date: Aug. 25, 2005

(54) Spring plunger probe

(76) Inventor: David L. Sanders, Camden Point, MO (US)

Correspondence Address: CHASE LAW FIRM L.C, 4400 COLLEGE BOULEVARD, SUITE 130, OVERLAND PARK, KS, 66211, US

(21) Appl. No.: 11/017,315

(22) Filed: Dec. 20, 2004

Related U.S. Application Data
(60) Provisional application No. 60/545,882, filed on Feb. 19, 2004.

(51) Int. Cl. G01R 31/02

(52) U.S. Cl. 324/761

(57) ABSTRACT

A single-piece contact probe includes a tip, coil and base formed from a single piece of electrically conductive material. A helical groove is machined around the center portion of the probe then a bore is drilled from the base toward the tip along the longitudinal axis of the probe to form the coils.

### CROSS REFERENCE TO RELATED APPLICATION

This application claims the benefit of a prior filed, co-pending provisional application Ser. No. 60/545,882, filed Feb. 19, 2004, entitled SPRING PLUNGER PROBE.

### FIELD OF THE INVENTION

This invention relates generally to battery contacts and interconnect probes and, in particular, to a single-piece contact probe which is used in electrical testing and battery contact applications.

### BACKGROUND OF THE INVENTION

In most probe designs, there are three distinct parts. First there is the plunger that makes contact with the target, DUT, battery contact, etc. The tip of the plunger that makes contact with the target can be of many different configurations, i.e. spear point, spherical point, crown point, etc., depending upon the target's geometry, cleanliness, contact material, for example. The other end of the plunger is housed in the second feature of the probe that is the barrel. The barrel has a three-fold purpose: 1) to capture or retain the plunger so it remains in place when the target is removed yet still allow the plunger to have compliancy (movement up and down or back and forth) 2) to transfer current or signal from the plunger to a source or receiver and 3) to supply a means of retaining the assembly in a housing, circuit board, etc. The third component of a probe is the spring that resides in the barrel between the end of the barrel and the plunger. The spring's sole purpose is to provide force to the plunger as it is moved into the barrel. It provides great compliancy for a probe by allowing the plunger to have large travel within a very small footprint. The compliancy of a probe provides the user great freedom in designing other components of a test fixture, machine, or device, and makes it useful for multiple applications.

Battery-type contacts and interconnect probe designs generally require compact, durable, highly reliable designs with circuit paths optimized for the best performance. These contacts are typically employed in battery charging applications, mobile telecommunication applications, docking applications, and other portable electronic devices in addition to applications for testing electronics, printed circuit boards and computer chips, for example. They may be used as either power conductors or as signal carriers and would be subject to a variety of environmental conditions.

There are inherent problems with the conventional probe that have led to a myriad of designs. The greatest problem is that which makes the probe very useful. The great compliancy of a probe also works against it in electrical performance. As compliancy simply means that the probe has moving components, this movement also creates poor electrical contact between components.

Plungers and barrels are dimensioned to provide spacing between them to allow for this movement to take place. Although this spacing is maintained as tight as possible (and still allow good manufacturing processes), any gap between two electrical contacts creates an open or failure in performance. Great efforts have been made in probe designs to ensure that contact between plunger and barrel always exist. But more than just contact is required; good, solid contact is necessary as intermittent contact or a light contact force results in intermittent opens or high resistances.

The probe industry has sought to ensure reliable contact between probe and plunger by permanently connecting the spring to both the plunger and barrel via a soldering or welding process. Although this provided a somewhat reliable contact, it resulted in a probe with appearances of intermittent electrical opens. This was due to the nature of the spring, a long, thin wire that is coiled into a much shorter component resulting in very large resistances. Resistances in the ohm range could be obtained if the spring becomes the only current path; so, when a designer is expecting resistances in the realm of a few milliohms, this appears as an open. If a significant amount of current passes through the spring, the high resistance results in a sudden heating of the probe possibly leading to the spring annealing, destroying the probe.

As is known in the art, current travels in parallel down all available paths in a quantity dependent upon the path's resistance. A spring, by nature of its design, has a very large resistance and will cause poor performance if it is the main current path. Likewise, large resistances between the barrel inner diameter (“ID”) and plunger, referred to as the contact resistance, will also lead to poor performance or failure. Large contact resistances are generally due to low contact force between barrel ID and plunger, poor conductive material of barrel and plunger including plating material and contaminates such as dirt, lint, or even some lubricants. Generally, good probe designs minimize the contact resistance by proper material selection, plating selection, attention to cleanliness/handling, and increasing the contact force between barrel ID and plunger through efforts called biasing, which is the action of forcing the plunger's bearing surface against the barrel ID.

### SUMMARY OF THE INVENTION

The present invention provides a probe in which the plunger, spring, and barrel are combined into one single component eliminating a sliding or moving contact. The one-piece probe includes of a conventional probe tip. A spring is machined into the central body of the probe. Unlike a conventional wire spring, the machined spring consists of considerably more volume of material that carries the current more effectively.

### BRIEF DESCRIPTION OF THE DRAWINGS

FIG. 1 is a side elevation view of a probe of the present invention illustrating a spring and plunger within a cross-sectional side view of a barrel;

FIG. 2 is a right end view of the probe of FIG. 1;

FIG. 3 is a side elevation view a spring and plunger of FIG. 1;

FIG. 4 is a right end view of the spring and plunger of FIG. 3;

FIG. 5 is a partial sectional view of a probe mounted in a fixture;

FIG. 6 is an enlarged view of one of the probes of FIG. 5;

FIG. 7 is a side elevation view of a double-ended probe;

FIG. 8 is a right end view of the probe of FIG. 7.

### DETAILED DESCRIPTION

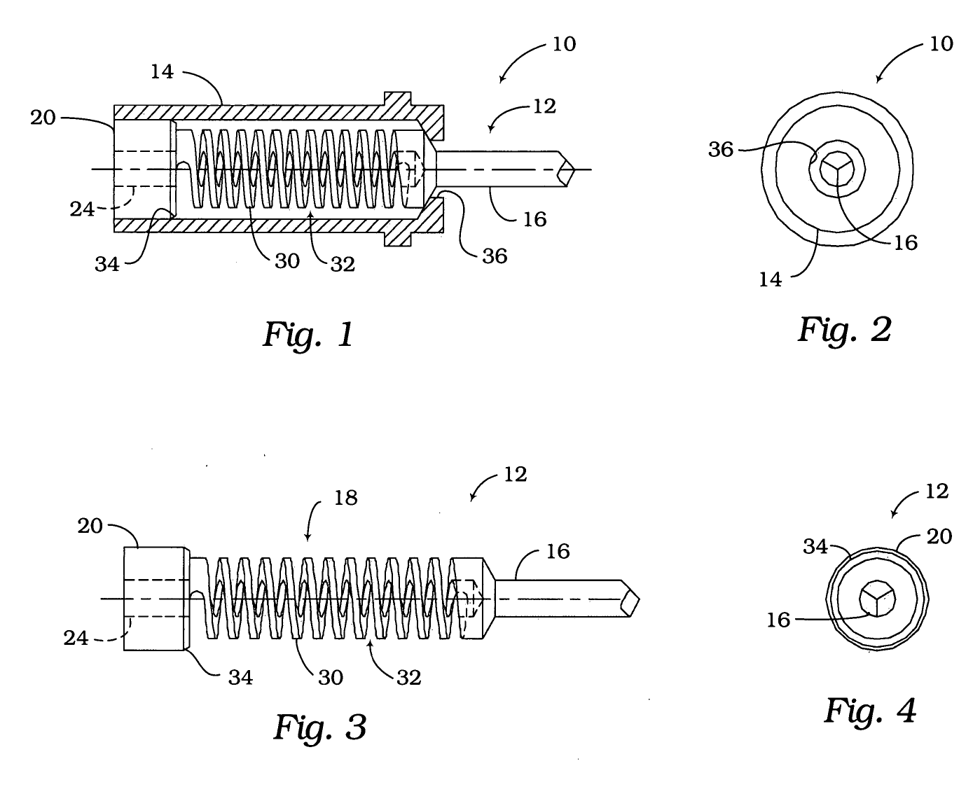

Referring to FIGS. 1-4, a spring probe of the present invention is generally indicated by reference numeral 10. Probe 10 includes a plunger 12 and a barrel 14. Plunger 12 is machined from a solid piece of stock material and includes a tip 16, a machined spring or coil 18, and a base 20. Plunger 12 is press-fit into barrel 14 to ensure good electrical contact between the probe 12 and the barrel 14 presenting, in essence, a one-piece probe 10. The plunger 12, spring 18, and barrel 14 are combined into one single component eliminating a sliding or moving contact between the plunger 12 and barrel 14.

The plunger 12 may be machined from a solid piece of stock material. The center portion of the stock material is machined to a diameter less than the base 20. The tip 16 is machined opposite the base 20. The plunger tip 16 may be configured in as many different ways as a conventional probe tip. A spiral cut is machined in the center portion of the stock material to a depth of the diameter of the hole 24. The hole 24 is then drilled in the end 20 along the longitudinal axis of the stock material. Unlike a conventional wire spring, the machined spring 18 consists of considerably higher volume of material that carries the current more effectively.

In one embodiment, the thickness of the spirals 30 of spring 18 may be 0.01 inch and the spacing 32 between spirals 30 may be 0.02 inch. The diameter of the coil may be approximately 0.110 inch with a coil thickness of approximately 0.06 inch.

As shown in FIG. 1, the base 20 of plunger 12 includes a beveled shoulder 34 to help guide the plunger 12 into the barrel 14. The plunger 12 is press-fit into the barrel 14. The plunger tip 16 extends through an aperture 36 in the barrel 14. The aperture 36 may be much larger than the diameter of the probe tip 16 to allow the plunger 12 to freely move in and out of the barrel 14 with little or no contact between the probe tip 16 and the aperture 36.

Resistance of a part is determined by the simple equation:
Resistance=rho×length/area.

As seen from this equation, the greater the cross-section and the shorter the part, the lower the resistance (rho being the resistivity of the material). Thus short contacts are better conductors. The length of the wire of a spring in a standard probe may be very long (many inches) and the cross-section may be very small resulting in a very high resistance. The machined spring 18 of plunger 12 results in much larger cross-section and a shorter spring length. The larger cross-section of the machined spring 18 also results in a stronger spring coil as the spring rate is proportional to the thickness and width of the rectangular cross-section. A stronger coil means simply fewer coils resulting in a shorter spring length. As a result of the machined spring 18, a more reasonable resistance can be expected as the current passes through the coils. Additionally, the machined spring 18 leads right into the base 20 of the plunger 12 from which connection may be made directly to an external power source or receiver (not shown).

Only one point of contact exists between the plunger 12 and target (not shown). Unlike a conventional probe, a second, sliding contact does not exist which might detrimentally affect the electrical performance. Reliability is improved because current does not have to transfer from one component to another but moves directly through the plunger 12 to the external connection.

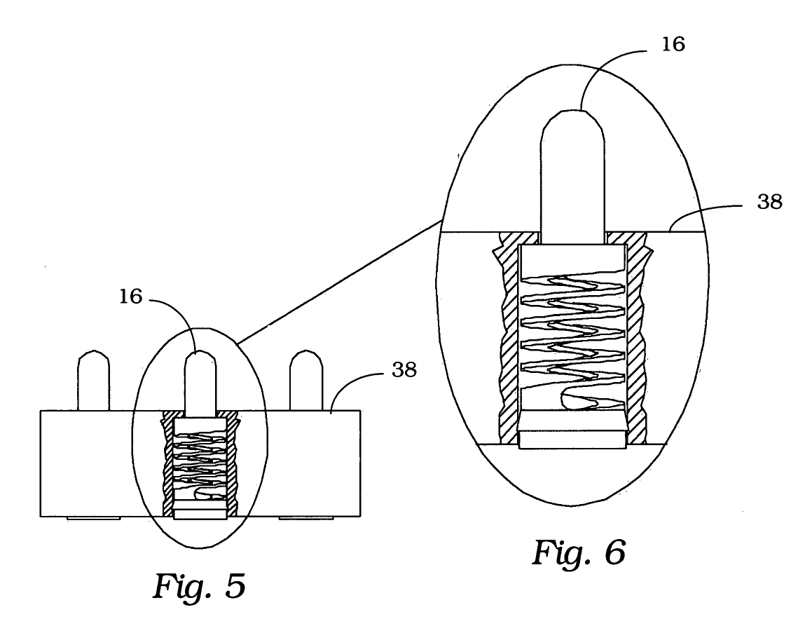

Referring to FIGS. 5 and 6, the spring plunger 12 may be pressed directly into a plastic housing 38 with the plunger 16 contacting a target (not shown) and the base 20 soldered to a board (not shown). As shown in FIG. 1, the spring plunger 12 may be pressed into a conventional probe barrel 14, which may then be soldered to a circuit board (not shown), for example. This latter use may enhance the electrical performance of the probe 10 as any contact between the plunger 12 and barrel 14 may reduce the resistance of the entire probe 10.

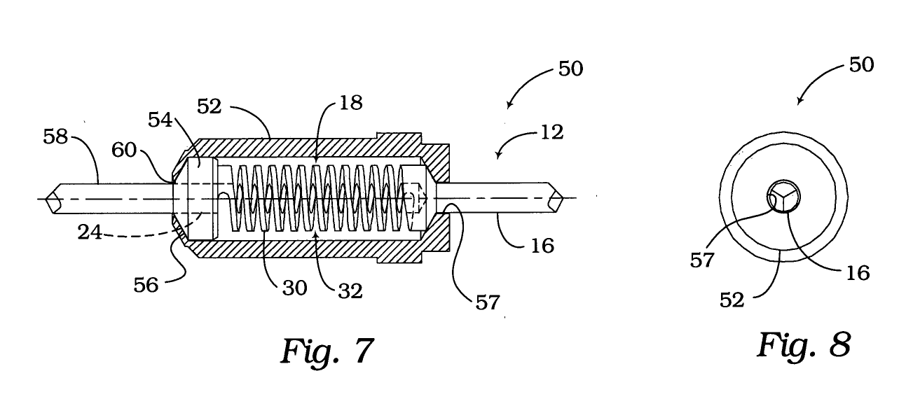

Referring to FIGS. 7 and 8, a double-ended probe is generally indicated by reference numeral 50. Many of the same components the double-ended probe 50 are the same as described hereinabove for probe 10 and thus the same reference numerals are used. Probe 50 includes a plunger 12 and a barrel 52. Plunger 12 is machined from a solid piece of stock material and includes a tip 16, a machined spring or coil 18, and a base 54. Base 54 includes a conical nose 56. A second tip 56 is pressed into aperture 24 in the base 54 to ensure good electrical continuity. Plunger 12 is slip-fit into barrel 54 with the tip 16 extending through aperture 57 at one end of barrel 52. The open end 58 of barrel 52 is crimped to retain the entire assembly. The plunger 12 is allowed to free-float in the barrel 52.

Other benefits of probe 10 may include a longer life as the friction component in a sliding contact is removed. Reliability of a conventional probe degrades over its life due to the wearing away of plating on the plunger and the inner diameter of the barrel and resulting high, inconsistent resistances. Also, the particulate from such wear has a tendency to interfere with the motion of the probe even to the point of binding the plunger up so no movement is possible. This particulate is readily observed in high friction probes by a black residue that falls out of the bottom of the barrel or works its way up the shaft of the plunger. Because the present design does not rely upon physical contact for electrical performance, frictional wear is not an issue. Also as a result of removing this friction issue, the smoothness of operation of the probe 10 may be greatly increased. Probe 50 has an improved life and reliability due to the larger cross-section and higher strength of the machined spring 18 over a conventional spring.

It is to be understood that while certain forms of this invention have been illustrated and described, is it not limited thereto except insofar as such limitations are included in the following claims.

1. A spring contact probe comprising:
a tip portion,
a middle helical spring portion, and
a base portion,
said middle helical spring portion separating said tip portion and said base portion,
wherein said spring contact probe has a unitary construction.

2. The spring contact probe of claim 1 further comprising a barrel having an open end and a reduced end wherein said tip portion extends from said reduced end and said base portion is secured within said open end.

3. The spring contact probe of claim 1 further comprising a second tip portion extending from said base portion and axially aligned with said tip portion.

4. A spring contact probe comprising:
a tip portion,
a middle portion extending from said tip portion,
a base portion extending from said middle portion,
an axial bore extending from said base portion through said middle portion,
said middle portion having a helical groove extending from an outside surface of said middle portion inwardly to said bore,
wherein said bore and said helical groove intersect to present a spring.

5. A spring contact probe of claim 4 further comprising a barrel, having an open end and a reduced end, wherein said tip portion extends from said reduced end and said base portion is secured within said open end.

6. A spring contact probe of claim 5 further comprising a barrel wherein said spring contact probe is secured within said barrel.

7. A spring probe comprising:
a plunger,
a helical spring extending from said plunger,
a base extending from said helical spring,
wherein said plunger, helical spring and base are machined from a single piece of electrically conductive material.

8. The spring contact probe of claim 7 further comprising a barrel having an open end and a reduced end wherein said tip portion extends from said reduced end and said base portion is secured within said open end.

9. The spring contact probe of claim 7 further comprising a second tip portion extending from said base portion and axially aligned with said tip portion.
